(19) United States
(12) Patent Application Publication
(10) Pub. No.: US 2026/0040770 A1
(43) Pub. Date: Feb. 5, 2026

(54) MOTHER SUBSTRATE AND MANUFACTURING METHOD OF MOTHER SUBSTRATE

(71) Applicant: Magnolia White Corporation, Tokyo (JP)

(72) Inventors: Masaichi OKUBO, Tokyo (JP); Nobuo IMAI, Tokyo (JP)

(73) Assignee: Magnolia White Corporation, Tokyo (JP)

(21) Appl. No.: 19/284,746

(22) Filed: Jul. 30, 2025

(30) Foreign Application Priority Data
Jul. 30, 2024 (JP) 2024-123120

(51) Int. Cl. H10K 59/122; H10K 59/12

(52) U.S. Cl. CPC H10K 59/122; H10K 59/1201

(57) ABSTRACT

According to one embodiment, a mother substrate includes a plurality of panel portions, a margin area, a lower electrode, a rib layer, and a partition provided in the margin area. The partition includes a bottom layer provided on the rib layer, a stem layer provided on the bottom layer, and an upper portion provided on the stem layer. The bottom layer has a protrusion portion protruding relative to a side surface of the stem layer. The upper portion has an overhang portion protruding relative to the side surface of the stem layer. The overhang portion has a notch overlapping the protrusion portion in plan view. The notch overlaps a boundary between the bottom layer and the stem layer in plan view.

### CROSS-REFERENCE TO RELATED APPLICATIONS

This application is based upon and claims the benefit of priority from Japanese Patent Application No. 2024-123120, filed Jul. 30, 2024, the entire contents of which are incorporated herein by reference.

### FIELD

Embodiments described herein relate generally to a mother substrate and a manufacturing method of a mother substrate.

### BACKGROUND

Recently, display devices with organic light-emitting diodes (OLED) applied thereto as display elements have been put into practical use. In the manufacturing of such display devices, an inspection is implemented to confirm whether the elements on the substrate are formed as designed. A technique for efficiently implementing this inspection is required.

### BRIEF DESCRIPTION OF THE DRAWINGS

FIG. 1 is a view showing a configuration example of a display device according to the first embodiment.

FIG. 2 is a schematic plan view showing an example of the layout of subpixels.

FIG. 3 is a schematic cross-sectional view of a display panel along the III-III line of FIG. 2.

FIG. 4 is a schematic plan view of a mother substrate according to the first embodiment.

FIG. 5 is a schematic plan view of a part of the mother substrate.

FIG. 6 is a schematic plan view showing an example of the configuration applicable to a test pattern of the mother substrate according to the first embodiment.

FIG. 7 is a schematic cross-sectional view of the mother substrate along the VII-VII line of FIG. 6.

FIG. 8 is an enlarged view of the area surrounded by the chained frame VIII in FIG. 6.

FIG. 9 is a schematic cross-sectional view of a partition along the IX-IX line of FIG. 8.

FIG. 10 is a schematic cross-sectional view of the partition along the X-X line of FIG. 8.

FIG. 11 is a flowchart showing an example of the manufacturing method of the display device according to the first embodiment.

FIG. 12A is a schematic cross-sectional view showing a process of forming panel portions in the mother substrate according to the first embodiment.

FIG. 12B is a schematic cross-sectional view showing a process following FIG. 12A.

FIG. 12C is a schematic cross-sectional view showing a process following FIG. 12B.

FIG. 12D is a schematic cross-sectional view showing a process following FIG. 12C.

FIG. 12E is a schematic cross-sectional view showing a process following FIG. 12D.

FIG. 12F is a schematic cross-sectional view showing a process following FIG. 12E.

FIG. 12G is a schematic cross-sectional view showing a process following FIG. 12F.

FIG. 12H is a schematic cross-sectional view showing a process following FIG. 12G.

FIG. 12I is a schematic cross-sectional view showing a process following FIG. 12H.

FIG. 12J is a schematic cross-sectional view showing a process following FIG. 12I.

FIG. 13A is a schematic cross-sectional view showing a process of removing a rib layer in a terminal portion.

FIG. 13B is a schematic cross-sectional view showing a process following FIG. 13A.

FIG. 14A is a schematic cross-sectional view showing an example of the process of removing a portion of an upper portion.

FIG. 14B is a schematic plan view showing an example of the process of removing a portion of the upper portion.

FIG. 14C is a schematic cross-sectional view showing a process following FIG. 14A.

FIG. 14D is a schematic cross-sectional view showing a process following FIG. 14B.

FIG. 15 is a schematic plan view showing an example of the configuration applicable to a test pattern of a mother substrate according to the second embodiment.

FIG. 16 is an enlarged view of the area surrounded by the chained frame XVI in FIG. 15.

FIG. 17 is a schematic cross-sectional view showing an example of the process of removing a portion of the upper portion.

FIG. 18 is a schematic plan view showing an example of the configuration applicable to a test pattern of a mother substrate according to the third embodiment.

FIG. 19 is a schematic cross-sectional view of the mother substrate along the XIX-XIX line of FIG. 18.

FIG. 20A is a schematic cross-sectional view showing an example of the process of forming a first portion.

FIG. 20B is a schematic cross-sectional view showing a process following FIG. 20A.

FIG. 20C is a schematic cross-sectional view showing a process following FIG. 20B.

FIG. 20D is a schematic cross-sectional view showing a process following FIG. 20C.

FIG. 20E is a schematic cross-sectional view showing a process following FIG. 20D.

### DETAILED DESCRIPTION

In general, according to one embodiment, a mother substrate includes a plurality of panel portions each including a display area and a surrounding area around the display area, a margin area around the plurality of panel portions, a lower electrode provided in the display area, a rib layer provided in the panel portion and the margin area and having a pixel aperture overlapping the lower electrode, and a first partition provided in the margin area. The first partition includes a first bottom layer provided on the rib layer, a first stem layer provided on the first bottom layer and having conductivity, and a first upper portion provided on the first stem layer. The first bottom layer has a protrusion portion protruding relative to a side surface of the first stem layer. The first upper portion has an overhang portion protruding relative to the side surface of the first stem layer. The overhang portion has a notch overlapping the protrusion portion in plan view. The notch overlaps a boundary between the first bottom layer and the first stem layer in plan view.

In general, according to another embodiment, a mother substrate includes a plurality of panel portions each including a display area and a surrounding area around the display area, a margin area around the plurality of panel portions, a lower electrode provided in the display area, a rib layer provided in the panel portion and the margin area and having a pixel aperture overlapping the lower electrode, and a first partition provided in the margin area. The first partition includes a first bottom layer provided on the rib layer, a first stem layer provided on the first bottom layer and having conductivity, a first upper portion provided on the first stem layer, a first partition aperture, a second partition aperture adjacent to the first partition aperture, and a first portion located between the first partition aperture and the second partition aperture. The first bottom layer has a protrusion portion protruding relative to a side surface of the first stem layer. An upper surface of the first stem layer is exposed in the first portion.

In general, according to one embodiment, a manufacturing method of a mother substrate includes preparing a substrate including a plurality of panel portions each including a display area and a surrounding area around the display area and a margin area around the plurality of panel portions, forming a lower electrode in the display area, forming a rib layer covering the plurality of panel portions and the margin area, forming a first partition in the margin area, the first partition including a first bottom layer formed on the rib layer, a first stem layer formed on the first bottom layer and having conductivity, and a first upper portion formed on the first stem layer, making a laser to scan in a second direction inclined with respect to a first direction in which the first partition extends to remove a portion of an overhang portion of the first upper portion, the portion protruding relative to a side surface of the first stem layer of the upper portion, and measuring a length of a protrusion portion of the first bottom layer, the protrusion portion protruding relative to the side surface of the first stem layer.

According to another embodiment, a manufacturing method of a mother substrate includes preparing a substrate including a plurality of panel portions each including a display area and a surrounding area around the display area and a margin area around the plurality of panel portions, forming a lower electrode in the display area, forming a rib layer covering the plurality of panel portions and the margin area, forming a first partition in the margin area, the first partition including a first bottom layer formed on the rib layer, a first stem layer formed on the first bottom layer and having conductivity, and a first upper portion formed on the first stem layer, forming a resist covering the first partition, simultaneously removing with a laser a portion of an overhang portion protruding relative to a side surface of the first stem layer of the first upper portion and a portion overlapping the overhang portion of the resist, and measuring a length of a protrusion portion of the first bottom layer, the protrusion portion protruding relative to the side surface of the first stem layer.

According to still another embodiment, a manufacturing method of a mother substrate includes preparing a substrate including a plurality of panel portions each including a display area and a surrounding area around the display area and a margin area around the plurality of panel portions, forming a lower electrode in the display area, forming a rib layer covering the plurality of panel portions and the margin area, forming a first partition in the margin area, the first partition including a first bottom layer formed on the rib layer, a first stem layer formed on the first bottom layer and having conductivity, a first upper portion formed on the first stem layer, a first partition aperture, and a second partition aperture adjacent to the first partition aperture, forming a resist from which at least a portion of the first upper portion is exposed between the first partition aperture and the second partition aperture, performing etching to remove a portion exposed from the resist of the first upper portion, and measuring a length of a protrusion portion of the first bottom layer, the protrusion portion protruding relative to a side surface of the first stem layer.

Embodiments can provide a mother substrate enabling an efficient inspection in manufacturing of a display device and a manufacturing method of the mother substrate.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis and a Z-axis orthogonal to each other are described to facilitate understanding as needed. A direction parallel to the X-axis is referred to as an X-direction. A direction parallel to the Y-axis is referred to as a Y-direction. A direction parallel to the Z-axis is referred to as a Z-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

### First Embodiment

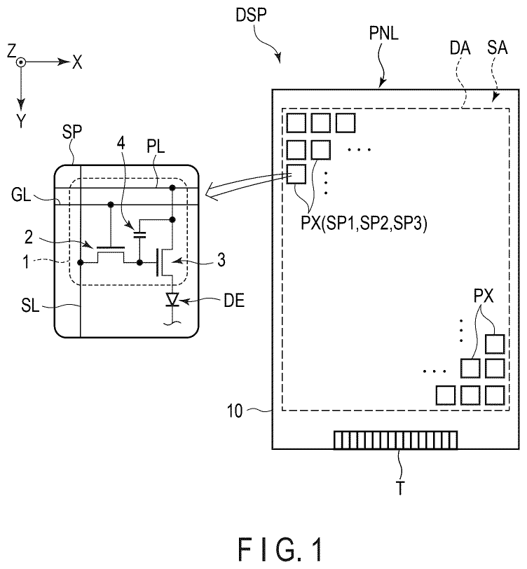

FIG. 1 is a view showing a configuration example of a display device DSP of the first embodiment. The display device DSP comprises a display panel PNL including an insulating substrate 10. The display panel PNL has a display area DA for displaying images and a surrounding area SA around the display area DA. The substrate 10 may be glass or a resinous film having flexibility.

In the present embodiment, the substrate 10 has a rectangular shape in plan view. The shape of the substrate 10 in plan view is not limited to a rectangle and may be another shape such as a square, a circle, or an oval.

The display area DA comprises a plurality of pixels PX arranged in a matrix in the X-direction and the Y-direction. Each pixel PX includes a plurality of subpixels SP that display different colors. The present embodiment assumes a case where each pixel PX includes a blue subpixel SP1, a green subpixel SP2, and a red subpixel SP3. However, each pixel PX may include a subpixel SP that exhibits another color such as white in addition to the subpixels SP1, SP2, and SP3 or instead of one of the subpixels SP1, SP2, and SP3.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

The display area DA has a plurality of scanning lines GL supplying the pixel circuit 1 of each subpixel SP with scanning signals, a plurality of signal lines SL supplying the pixel circuit 1 of each subpixel SP with video signals, and a plurality of power lines PL. In the example of FIG. 1, the scanning lines GL and the power lines PL extend in the X-direction, and the signal lines SL extend in the Y-direction.

A gate electrode of the pixel switch 2 is connected to the scanning line GL. One of a source electrode and a drain electrode of the pixel switch 2 is connected to the signal line SL. The other is connected to a gate electrode of the drive transistor 3 and the capacitor 4. In the drive transistor 3, one of a source electrode and a drain electrode is connected to the power line PL and the capacitor 4. The other is connected to the display element DE.

The configuration of the pixel circuit 1 is not limited to the example of the figure. For example, the pixel circuit 1 may comprise more thin-film transistors and capacitors.

The display device DSP further comprises a terminal portion T provided in the surrounding area SA. For example, a flexible printed circuit board is connected to the terminal portion T. The signals and voltage for driving the pixel circuit 1 are input to the display device DSP via these flexible printed circuit boards and the terminal portion T.

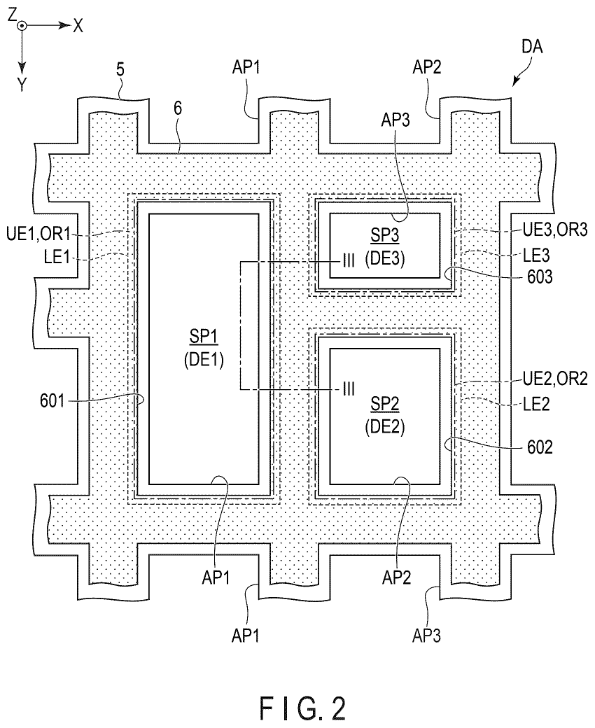

FIG. 2 is a schematic plan view showing an example of the layout of the subpixels SP1, SP2, and SP3. In the example of FIG. 2, each of the subpixels SP2 and SP3 is adjacent to the subpixel SP1 in the X-direction. Further, the subpixels SP2 and SP3 are arranged in the Y-direction.

When the subpixels SP1, SP2, and SP3 are arranged in this layout, in the display area DA, a column in which the subpixels SP2 and SP3 are alternately arranged in the Y-direction and a column in which the plurality of subpixels SP1 are repeatedly arranged in the Y-direction are formed. These columns are alternately arranged in the X-direction. The layout of the subpixels SP1, SP2, and SP3 is not limited to the example of FIG. 2.

A rib layer 5 is provided in the display area DA. The rib layer 5 has pixel apertures AP1, AP2, and AP3 in the respective subpixels SP1, SP2, and SP3. In the example of FIG. 2, the pixel aperture AP1 is greater than the pixel aperture AP2, and the pixel aperture AP2 is greater than the pixel aperture AP3. That is, among the subpixels SP1, SP2, and SP3, the aperture ratio of the subpixel SP1 is the greatest, and the aperture ratio of the subpixel SP3 is the least. The size and the shape of each of the pixel apertures AP1, AP2, and AP3 are not limited to the illustrated example.

The subpixel SP1 comprises a lower electrode LE1, an upper electrode UE1, and an organic layer OR1, which overlap the pixel aperture AP1. The subpixel SP2 comprises a lower electrode LE2, an upper electrode UE2, and an organic layer OR2, which overlap the pixel aperture AP2. The subpixel SP3 comprises a lower electrode LE3, an upper electrode UE3, and an organic layer OR3, which overlap the pixel aperture AP3.

Portions that overlap the pixel aperture AP1 of the lower electrode LE1, the upper electrode UE1, and the organic layer OR1 constitute a display element DE1 of the subpixel SP1. Portions that overlap the pixel aperture AP2 of the lower electrode LE2, the upper electrode UE2, and the organic layer OR2 constitute a display element DE2 of the subpixel SP2. Portions that overlap the pixel aperture AP3 of the lower electrode LE3, the upper electrode UE3, and the organic layer OR3 constitute a display element DE3 of the subpixel SP3. Each of the display elements DE1, DE2, and DE3 may further include a cap layer to be described later. The rib layer 5 surrounds each of the display elements DE1, DE2, and DE3.

In the display area DA, a partition 6 (the second partition) having conductivity is provided above the rib layer 5. The partition 6 functions as lines that apply common voltage to the upper electrodes UE1, UE2, and UE3. The partition 6 entirely overlaps the rib layer 5 and has the same planar shape as that of the rib layer 5.

Specifically, the partition 6 has a partition aperture 601 in the subpixel SP1, a partition aperture 602 in the subpixel SP2, and a partition aperture 603 in the subpixel SP3. The respective partition apertures 601, 602, and 603 are greater than the pixel apertures AP1, AP2, and AP3 and surround the pixel apertures AP1, AP2, and AP3. The respective partition apertures 601, 602, and 603 entirely overlap the display elements DE1, DE2, and DE3. That is, the partition 6 surrounds the display elements DE1, DE2, and DE3.

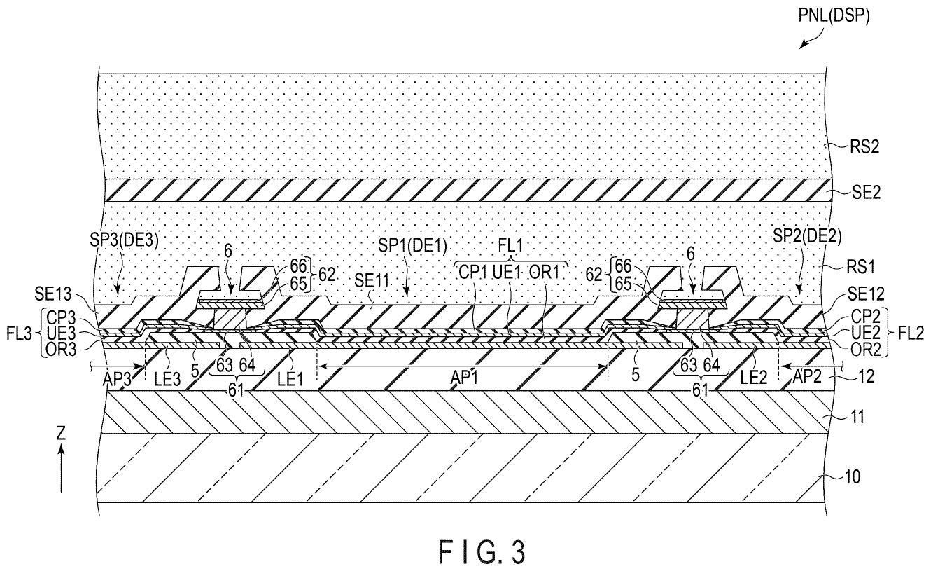

FIG. 3 is a schematic cross-sectional view of the display panel PNL along the III-III line of FIG. 2. A circuit layer 11 is provided on the substrate 10 described above. The circuit layer 11 includes various circuits and lines such as the pixel circuit 1, the scanning lines GL, the signal lines SL, and the power lines PL shown in FIG. 1. The circuit layer 11 is covered with an organic insulating layer 12. The organic insulating layer 12 functions as a planarization film, which planarizes irregularities formed by the circuit layer 11.

The lower electrodes LE1, LE2, and LE3 are provided on the organic insulating layer 12. The rib layer 5 is provided on the organic insulating layer 12 and the lower electrodes LE1, LE2, and LE3. End portions of the lower electrodes LE1, LE2, and LE3 are covered with the rib layer 5. Although not shown in the section of FIG. 3, the lower electrodes LE1, LE2, and LE3 are connected to the respective pixel circuits 1 of the circuit layer 11 through respective contact holes provided in the organic insulating layer 12.

The partition 6 includes a lower portion 61 having conductivity and provided on the rib layer 5 and an upper portion 62 (the second upper portion) provided on the lower portion 61. The upper portion 62 has a width greater than that of the lower portion 61. This configuration allows both end portions of the upper portion 62 to protrude relative to the side surfaces of the lower portion 61. This shape of the partition 6 is called an overhang shape.

In the example of FIG. 3, the lower portion 61 has a bottom layer 63 (the second bottom layer) provided on the rib layer 5, and a stem layer 64 (the second stem layer) having conductivity and provided on the bottom layer 63. For example, the bottom layer 63 is thinner than the stem layer 64. In the example of FIG. 3, both end portions of the bottom layer 63 protrude relative to the side surfaces of the stem layer 64.

In the example of FIG. 3, the upper portion 62 has a first thin film 65 and a second thin film 66 provided on the first thin film 65. For example, the width of the second thin film 66 is slightly less than that of the first thin film 65. The configuration is not limited to this example. The first thin film 65 and the second thin film 66 may have the equivalent width.

The organic layer OR1 contacts the lower electrode LE1 through the pixel aperture AP1. The upper electrode UE1 is provided on the organic layer OR1 and faces the lower electrode LE1. The organic layer OR2 contacts the lower electrode LE2 through the pixel aperture AP2. The upper electrode UE2 is provided on the organic layer OR2 and faces the lower electrode LE2. The organic layer OR3 contacts the lower electrode LE3 through the pixel aperture AP3. The upper electrode UE3 is provided on the organic layer OR3 and faces the lower electrode LE3. The upper electrodes UE1, UE2, and UE3 contact the lower portions 61 of the partition 6.

The display element DE1 includes a cap layer CP1 provided on the upper electrode UE1. The display element DE2 includes a cap layer CP2 provided on the upper electrode UE2. The display element DE3 includes a cap layer CP3 provided on the upper electrode UE3. The cap layers CP1, CP2, and CP3 function as optical adjustment layers, which improve the extraction efficiency of the light emitted from the organic layers OR1, OR2, and OR3, respectively.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3. The partition 6 surrounds the stacked films FL1, FL2, and FL3.

Sealing layers SE11, SE12, and SE13, which respectively cover the stacked films FL1, FL2, and FL3 are respectively provided in the subpixels SP1, SP2, and SP3. The sealing layer SE11 continuously covers the display element DE1 and the partition 6 around the display element DE1. The sealing layer SE12 continuously covers the display element DE2 and the partition 6 around the display element DE2. The sealing layer SE13 continuously covers the display element DE3 and the partition 6 around the display element DE3.

In the example of FIG. 3, the sealing layer SE11 located on the partition 6 between the subpixels SP1 and SP2 is spaced apart from the sealing layer SE12 located on this partition 6. The sealing layer SE11 located on the partition 6 between the subpixels SP1 and SP3 is spaced apart from the sealing layer SE13 located on this partition 6. Two of the sealing layers SE11, SE12, and SE13 may contact each other above the partition 6.

For example, a gap is formed between the respective sealing layers SE11, SE12, and SE13 and the upper portion 62 of the partition 6. The stacked films FL1, FL2, and FL3 may be provided in at least part of these gaps.

The sealing layers SE11, SE12, and SE13 are covered with a resin layer RS1. The resin layer RS1 is covered with the sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a touch panel, a protective film, or a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as a polyimide. Each of the rib layer 5 and the sealing layers SE11, SE12, SE13, and SE2 is formed of an inorganic insulating material such as a silicon nitride (SiNx), a silicon oxide (SiOx), or a silicon oxynitride (SiON). In an example, the rib layer 5 is formed of a silicon oxynitride, and each of the sealing layers SE11, SE12, SE13, and SE2 is formed of a silicon nitride. Each of the resin layers RS1 and RS2 is formed of, for example, a resinous material (organic insulating materials) such as an epoxy resin or an acrylic resin.

Each of the lower electrodes LE1, LE2, and LE3 has a reflective layer formed of, for example, silver, and a pair of conductive oxide layers covering the upper and lower surfaces of the reflective layer. Each of the conductive oxide layers can be formed of, for example, a transparent conductive oxide such as an indium tin oxide (ITO), an indium zinc oxide (IZO), or an indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 is composed of a plurality of thin films including a light emitting layer. In an example, the organic layers OR1, OR2, and OR3 have a structure in which a hole-injection layer, a hole-transport layer, an electron blocking layer, a light emitting layer, a hole blocking layer, an electron-transport layer, and an electron-injection layer are stacked in this order in the Z-direction. The organic layers OR1, OR2, and OR3 each may comprise other structures such as a tandem structure including a plurality of light emitting layers.

Each of the cap layers CP1, CP2, and CP3 comprises, for example, a multilayer structure in which a plurality of transparent layers are stacked. These transparent layers could include a layer formed of an inorganic material and a layer formed of an organic material. The transparent layers have refractive indices different from one another. For example, the refractive indices of these transparent layers are different from the refractive indices of the upper electrodes UE1, UE2, and UE3 and the refractive indices of the sealing layers SE11, SE12, and SE13. At least one of the cap layers CP1, CP2, and CP3 may be omitted.

Each of the bottom layer 63 and stem layer 64 of the lower portion 61 of the partition 6 is formed of, for example, a metal material. For the metal material of the bottom layer 63, for example, molybdenum (Mo), titanium (Ti), a titanium nitride (TiN), a molybdenum-tungsten alloy (MoW), or a molybdenum-niobium alloy (MoNb) can be used. For the metal material of the stem layer 64, for example, aluminum (Al), an aluminum-neodymium alloy (AlNd), an aluminum-yttrium alloy (AlY), or an aluminum-silicon alloy (AlSi) can be used. For example, at least one of the bottom layer 63 and the stem layer 64 may comprise a multilayer structure in which a plurality of layers are stacked. The stem layer 64 may include a layer formed of an insulating material.

The first thin film 65 of the partition 6 is formed of, for example, a metal material. The second thin film 66 of the partition 6 is formed of, for example, a conductive oxide. For the metal material forming the first thin film 65, for example, titanium, a titanium nitride, molybdenum, tungsten, a molybdenum-tungsten alloy, or a molybdenum-niobium alloy can be used. For the conductive oxide forming the second thin film 66, for example, an ITO or an IZO can be used. The upper portion 62 may comprise three or more layers or may be composed of a single layer. The upper portion 62 may further include a layer formed of an insulating material.

Common voltage is applied to the partition 6. This common voltage is applied to each of the upper electrodes UE1, UE2, and UE3, which contact the lower portions 61. The lower electrodes LE1, LE2, and LE3 each are supplied with pixel voltages according to the video signals of the signal lines SL through the pixel circuits 1 of the respective subpixels SP1, SP2, and SP3.

The organic layers OR1, OR2, and OR3 emit light in response to the application of a voltage. Specifically, when a potential difference is formed between the lower electrode LE1 and the upper electrode UE1, the light emitting layer of the organic layer OR1 emits light in the blue wavelength range. When a potential difference is formed between the lower electrode LE2 and the upper electrode UE2, the light emitting layer of the organic layer OR2 emits light in the green wavelength range. When a potential difference is formed between the lower electrode LE3 and the upper electrode UE3, the light emitting layer of the organic layer OR3 emits light in the red wavelength range.

In another example, the light emitting layers of the organic layers OR1, OR2, and OR3 may emit light of the same color (for example, white). In this case, the display device DSP may comprise a color filter that converts the light emitted from the light emitting layers into light of the colors corresponding to those of the subpixels SP1, SP2, and SP3. In addition, the display device DSP may comprise a layer including quantum dots that are excited by the light emitted from the light emitting layers to generate the light of the colors corresponding to those of the subpixels SP1, SP2, and SP3.

In the manufacturing of the display device DSP, a large mother substrate is fabricated, the mother substrate comprising a plurality of areas (panel portions) each corresponding to the display panel PNL. The following describes a configuration applicable to this mother substrate.

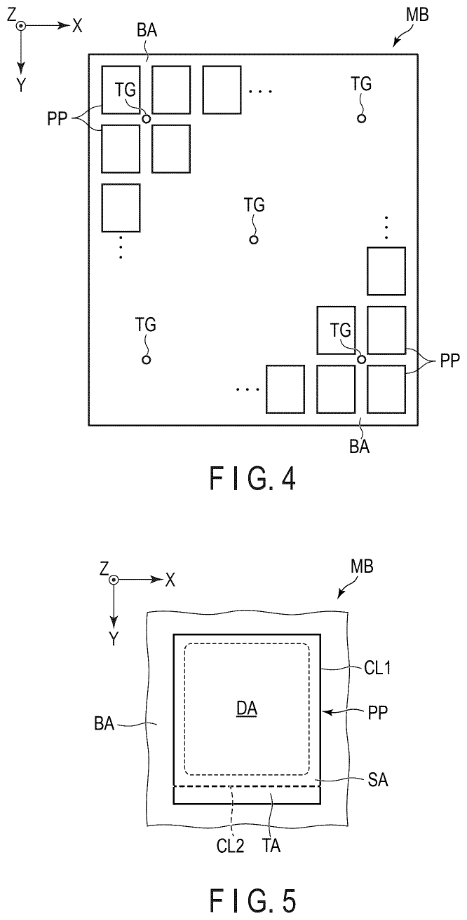

FIG. 4 is a schematic plan view of a mother substrate MB (a mother substrate for a display device) according to the first embodiment. For example, the mother substrate MB has a rectangular shape as shown in the figure. However, the mother substrate MB may have another shape such as a circular shape.

The mother substrate MB comprises a plurality of panel portions PP provided in a matrix and a margin area BA around these panel portions PP. In the example of FIG. 4, the panel portions PP are arranged in the X-direction and the Y-direction via the margin area BA. However, at least two of the panel portions PP provided in the mother substrate MB may be adjacent to each other without intervention of the margin area BA.

The mother substrate MB further comprises at least one test pattern TG. In the example of FIG. 4, a plurality of test patterns TG are provided in the margin area BA. The layout position and the number of these test patterns TG are not particularly limited. However, in an example, the test patterns TG are preferably dispersed at several positions such as the vicinity of the end portion and the center of the mother substrate MB.

FIG. 5 is a schematic plan view of a part of the mother substrate MB. This figure focuses attention on one panel portion PP. The outer shape of the panel portion PP corresponds to a cut line CL1 for cutting out the panel portion PP from the mother substrate MB.

Each panel portion PP has the display area DA and the surrounding area SA. Further, the surrounding area SA includes an inspection area TA. In the inspection area TA, an inspection pad for inspecting the operation of the display panel PNL and the like are provided.

In each panel portion PP, a cut line CL2 is formed. This cut line CL2 divides the panel portions PP into a portion that includes the display area DA and a portion that includes the inspection area TA.

In the manufacturing of the display device DSP, the panel portion PP is first cut out from the mother substrate MB along the cut line CL1. Further, an inspection using the inspection pad is implemented for the cut panel portion PP. After this inspection, the inspection area TA is separated from the panel portion PP along the cut line CL2.

The test patterns TG shown in FIG. 4 may be provided in the surrounding area SA as well as the margin area BA. For example, the test pattern TG may be provided in the inspection area TA. In this case, the test pattern TG does not remain in the panel portion PP from which the inspection area TA has been cut along the cut line CL2. In a case where the test patterns TG are provided in the margin area BA as shown in FIG. 4 as well, the test patterns TG do not remain in the panel portions PP from which the inspection areas TA have been cut along the cut line CL2.

In another example, the test pattern TG may be provided in the portion excluding the inspection area TA from the surrounding area SA. In this case, the test pattern TG remains in the panel portion PP from which the inspection area TA has been cut along the cut line CL2.

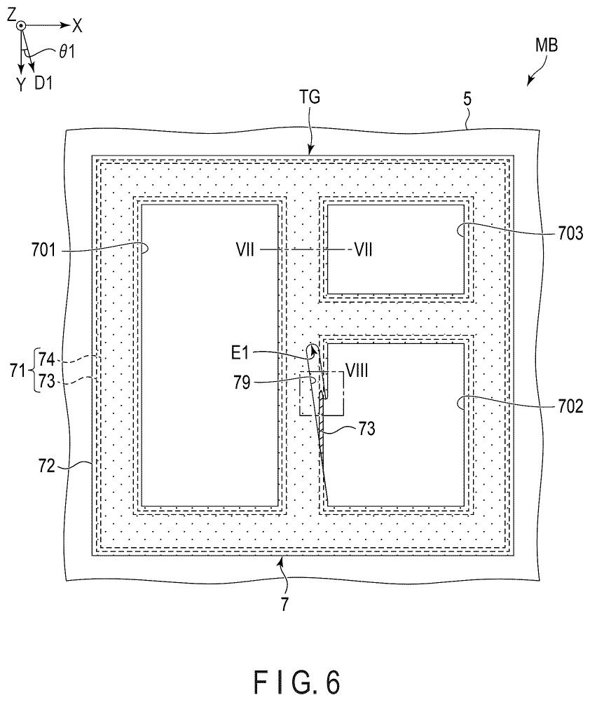

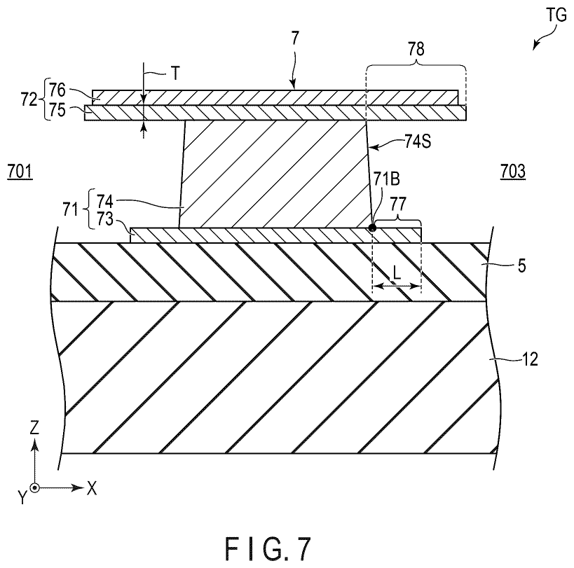

FIG. 6 is a schematic plan view showing an example of the configuration applicable to the test pattern TG of the mother substrate MB according to the first embodiment. FIG. 7 is a schematic cross-sectional view of the mother substrate MB along the VII-VII line of FIG. 6. FIG. 7 omits the illustration of the components below the organic insulating layer 12.

As shown in FIG. 6, the test pattern TG is composed of the rib layer 5 and a partition 7 (the first partition). The rib layer 5 is provided across the panel portions PP and the margin area BA shown in FIG. 4. The partition 7 is provided in the margin area BA. The partition 7 is provided in the surrounding area SA. The partition 7 extends in the X-direction and the Y-direction (the first direction) and is formed in a grating shape. In the example of FIG. 6, the partition 7 has partition apertures 701, 702, and 703.

For example, the shapes and layout of the partition apertures 701, 702, and 703 are the same as those of the respective partition apertures 601, 602, and 603 shown in FIG. 2. The partition 7 may have an aperture or a plurality of apertures having shapes different from those of the partition apertures 601, 602, and 603.

The partition 7 includes a lower portion 71 provided on the rib layer 5 and having conductivity and an upper portion 72 (the first upper portion) provided on the lower portion 71 as shown in FIG. 6 and FIG. 7. The upper portion 72 has a width greater than that of the lower portion 71. This configuration allows both end portions of the upper portion 72 to protrude relative to the side surfaces of the lower portion 71.

The lower portion 71 has a bottom layer 73 (the first bottom layer) provided on the rib layer 5 and a stem layer 74 (the first stem layer) provided on the bottom layer 73 and having conductivity. For example, the bottom layer 73 is thinner than the stem layer 74.

The bottom layer 73 has a protrusion portion 77 protruding relative to a side surface 74S of the stem layer 74. The length in the X-direction of the protrusion portion 77 is defined as a length L. The length L corresponds to a length in the X-direction of a part between the side surface 74S of the stem layer 74 and the end portion of the bottom layer 73. More specifically, the length L corresponds to a length in the X-direction of the part between a boundary 71B, between the side surface 74S and the bottom layer 73, and the end portion of the bottom layer 73. In the example shown in FIG. 7, the side surface 74S is formed in a tapered shape. FIG. 6 shows the portions that overlap the upper portion 72 of the outer shape of the bottom layer 73 and the stem layer 74 by broken lines.

The upper portion 72 has a first thin film 75 and a second thin film 76 provided on the first thin film 75. For example, the width of the second thin film 76 is slightly less than that of the first thin film 75. The configuration is not limited to this example. The first thin film 75 and the second thin film 76 may have the equivalent width.

The thickness of the first thin film 75 is defined as a thickness T. In an example, the thickness T is 100 nm or less in the first embodiment.

The upper portion 72 has an overhang portion 78 protruding relative to the side surface 74S of the stem layer 74. In the example shown in FIG. 7, the length in the X-direction of the overhang portion 78 is greater than the length L. That is, the protrusion portion 77 is completely covered with the overhang portion 78 in plan view.

The partition 7 can be formed in the same process as that of the partition 6. In this case, the bottom layer 73 is formed of the same material as that of the bottom layer 63, the stem layer 74 is formed of the same material as that of the stem layer 64, the first thin film 75 is formed of the same material as that of the first thin film 65, and the second thin film 76 is formed of the same material as that of the second thin film 66.

As shown in FIG. 6, the upper portion 72 has a trench portion 79 extending in a direction D1 (the second direction) inclined anticlockwise at an angle θ1 with respect to the Y-direction. For example, the angle θ1 is an acute angle. In the example of FIG. 6, the trench portion 79 is provided between the partition apertures 701 and 702 (the first partition aperture and the second partition aperture). The extending direction of the trench portion 79 is not limited to this example. For example, the trench portion 79 may extend in a direction inclined clockwise at the angle θ1 with respect to the Y-direction. The position of the trench portion 79 is not limited to the illustrated example.

The trench portion 79 has an end portion E1 overlapping the stem layer 74 in plan view. The end portion E1 is formed in an arcuate shape. The trench portion 79 reaches the partition aperture 702. A portion of the upper portion 72 is lost and a portion of the bottom layer 73 (the portion indicated by hatch lines) is exposed between the trench portion 79 and the partition aperture 702.

The trench portion 79 is formed by irradiating the upper portion 72 with laser light. This point is to be described later in detail. Irradiating the overhang portion 78 with this laser light removes the portion of the overhang portion 78 and makes a portion of the bottom layer 73 exposed.

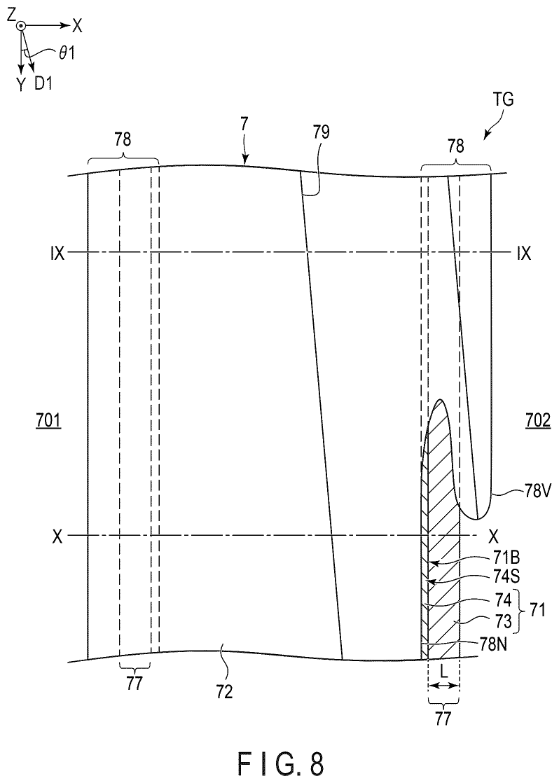

FIG. 8 is an enlarged view of the area surrounded by the chained frame VIII in FIG. 6. FIG. 8 shows the portions that do not overlap the upper portion 72 of the bottom layer 73 and the stem layer 74 by hatch lines.

The overhang portion 78 has a notch 78N and a convex portion 78V. The notch 78N corresponds to the portion removed from the overhang portion 78 by the above laser light. The notch 78N overlaps the protrusion portion 77 and is adjacent to the trench portion 79 in the direction DI in plan view. The notch 78N overlaps the boundary 71B between the bottom layer 73 and the stem layer 74 in plan view.

In the Y-direction, the convex portion 78V is formed in a convex shape and is adjacent to the notch 78N. The convex portion 78V is spaced apart from the stem layer 74. A portion of the notch 78N is provided between the convex portion 78V and the stem layer 74. In the example shown in FIG. 8, a portion of the convex portion 78V overlaps the trench portion 79. The convex portion 78V is formed by the laser light scanning in the direction D1.

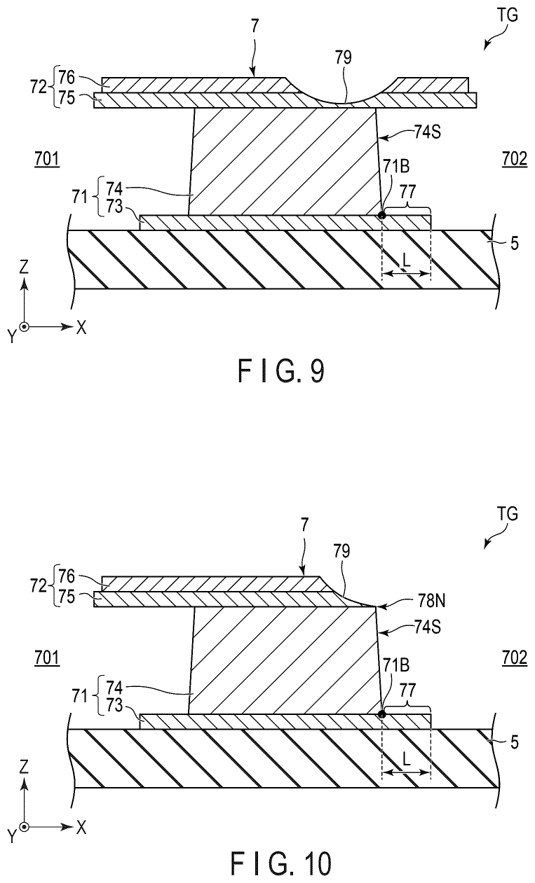

FIG. 9 is a schematic cross-sectional view of the partition 7 along the IX-IX line of FIG. 8. The trench portion 79 is recessed toward the lower portion 71. In the example of FIG. 9, the trench portion 79 is formed on the first thin film 75 and the second thin film 76. The trench portion 79 may reach the stem layer 74. The width and the depth of the trench portion 79 change according to outputs and the like of the laser light for forming the trench portion 79.

FIG. 10 is a schematic cross-sectional view of the partition 7 along the X-X line of FIG. 8. In FIG. 10, the trench portion 79 reaches the boundary between the lower surface of the upper portion 72 and the side surface 74S of the stem layer 74. Thus, in FIG. 10, the partition 7 does not have the overhang portion 78 on the partition aperture 702 side.

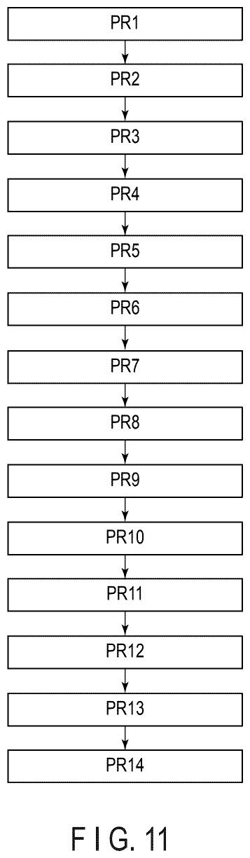

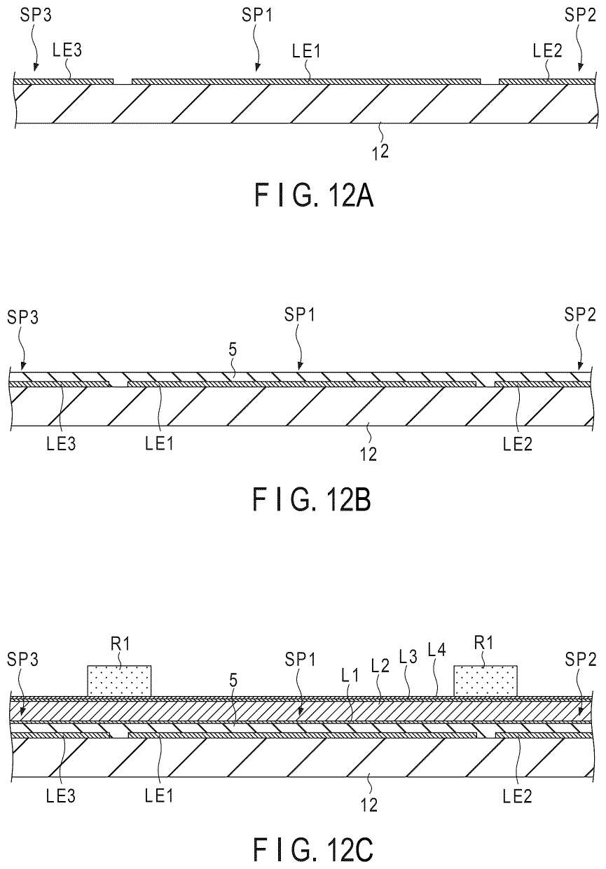

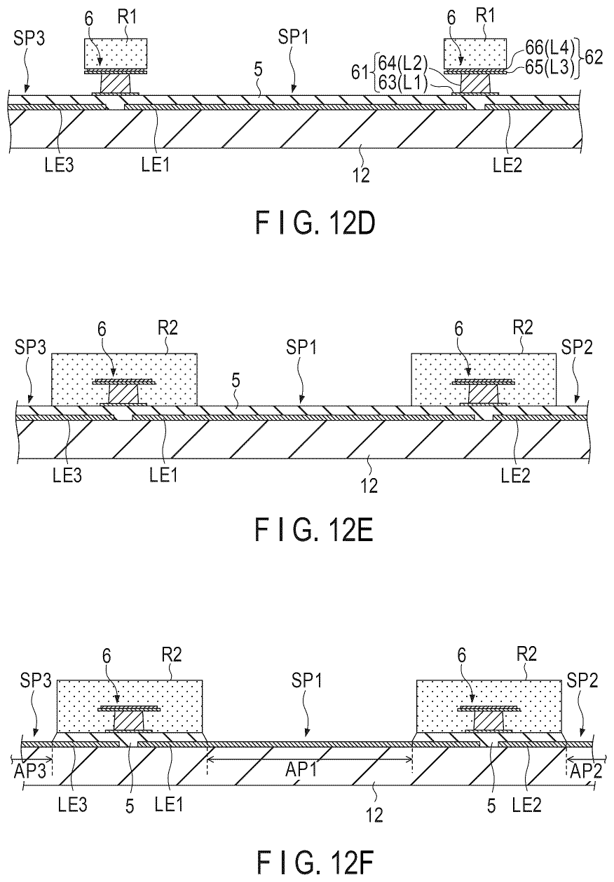

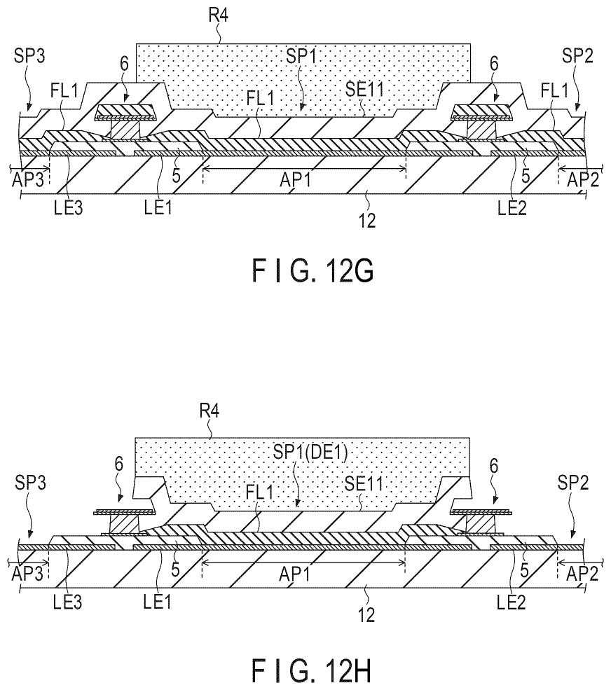

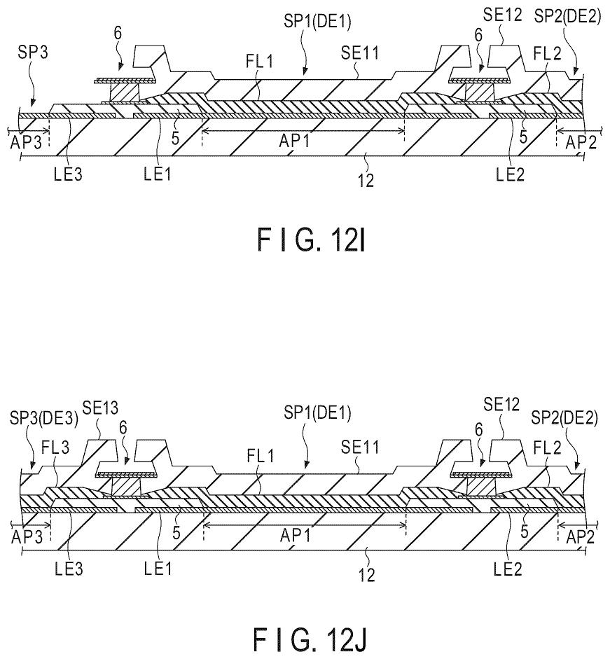

The following describes an example of the manufacturing method of the display device DSP. FIG. 11 is a flowchart showing an example of the manufacturing method of the display device DSP. FIG. 12A to FIG. 12J are schematic cross-sectional views showing the process of forming the panel portions PP in the mother substrate MB. FIG. 12A to FIG. 12J mainly focus on the display area DA and omit the illustration of the components below the organic insulating layer 12.

In the formation of the panel portions PP, first, the circuit layer 11 and the organic insulating layer 12 are formed on the substrate 10 of the mother substrate MB (the process PRI in FIG. 11). Subsequently, the lower electrodes LE1, LE2, and LE3 are formed on the organic insulating layer 12 as shown in FIG. 12A (the process PR2 in FIG. 11).

Subsequently, the rib layer 5 covering the lower electrodes LE1, LE2, and LE3 is formed in the entire mother substrate MB as shown in FIG. 12B (the process PR3 in FIG. 11). At this time, the pixel apertures AP1, AP2, and AP3 are not provided in the rib layer 5. The rib layer 5 can be formed by chemical vapor deposition (CVD).

After the formation of the rib layer 5, a process for forming the partition 6 is performed (the processes PR4 and PR5 in FIG. 11). In this process PR4, a first layer L1 to be processed into the bottom layer 63, a second layer L2 to be processed into the stem layer 64, a third layer L3 to be processed into the first thin film 65, and a fourth layer L4 to be processed into the second thin film 66 are subsequently formed in the entire mother substrate MB as shown in FIG. 12C. Further, a resist R1 is provided on the fourth layer L4. The resist R1 has been patterned into the shape of the partition 6. The first layer LI, the second layer L2, the third layer L3, and the fourth layer L4 are formed by, for example, sputtering.

In the subsequent process PR5, the first layer L1, the second layer L2, the third layer L3, and the fourth layer L4 are patterned using the resist R1 as a mask. In an example, the first layer LI is formed of a titanium nitride, the second layer L2 is formed of aluminum, the third layer L3 is formed of titanium, and the fourth layer L4 is formed of an ITO. In this case, the process PR5 may include wet etching for removing the portion exposed from the resist R1 of the fourth layer L4, dry etching for removing the portions exposed from the resist R1 of the first layer L1, the second layer L2, and the third layer L3, and wet etching for reducing the width of the second layer L2. The etching performed in the process PR5 is appropriately selected based on the structure and material of the partition 6.

The process PR5 completes the formation of the partition 6 in the display area DA as shown in FIG. 12D. After the formation of the partition 6, the resist R1 is removed (stripped). In the above wet etching for reducing the width of the second layer L2, the second thin film 66 (the fourth layer L4) could be slightly corroded. When this corrosion occurs, the width of the second thin film 66 becomes less than that of the first thin film 65.

Subsequently, a process for providing the pixel apertures AP1, AP2, and AP3 is performed (the process PR6 in FIG. 11). In this process PR6, a resist R2 covering the partition 6 is formed as shown in FIG. 12E. Further, dry etching for the rib layer 5 is performed using the resist R2 as a mask. This dry etching forms the pixel apertures AP1, AP2, and AP3 that respectively make the lower electrodes LE1, LE2, and LE3 exposed on the rib layer 5 as shown in FIG. 12F. After the dry etching described above, the resist R2 is removed (stripped).

After the process PR6, a process for removing the rib layer 5 in the terminal portion T shown in FIG. 1 is performed (the process PR7 in FIG. 11).

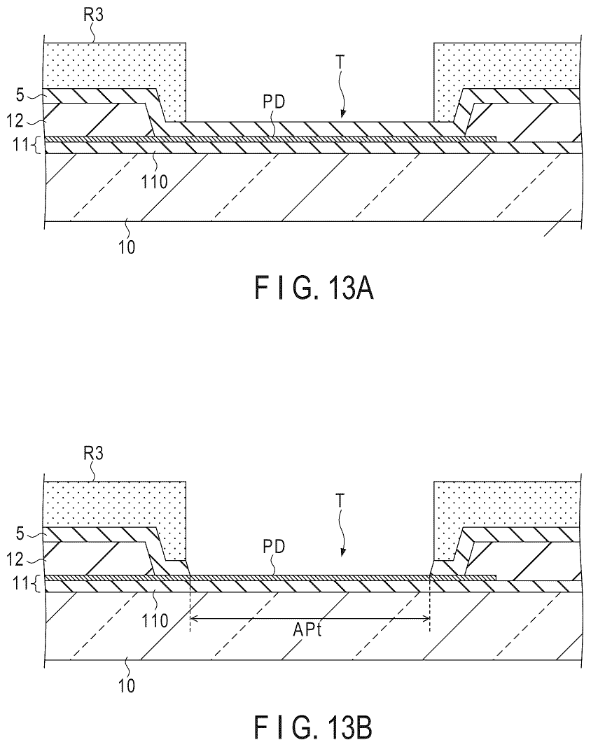

FIG. 13A and FIG. 13B are schematic cross-sectional views of the terminal portion T for explaining the process PR7. As shown in these figures, the terminal portion T comprises a conductive pad PD (a conductive layer). The pad PD is provided on an insulating layer 110 formed of, for example, an inorganic insulating material. The pad PD and the insulating layer 110 are included in the circuit layer 11 shown in, for example, FIG. 3. For example, the peripheral portion of the pad PD is covered with the organic insulating layer 12.

The pad PD is formed in the surrounding area SA prior to the process PR3 of forming the rib layer 5. In the process PR3, the pad PD is covered with the rib layer 5. Thus, at the time of completion of the process PR6, the pad PD is covered with the rib layer 5 as shown in FIG. 13A. In the process PR7, a resist R3 has a shape open on the upper side of the pad PD is provided on the rib layer 5. Further, dry etching for the rib layer 5 is performed using the resist R3 as a mask. This process forms a terminal aperture APt, which overlaps the pad PD and from which the pad PD is exposed is formed in the rib layer 5 as shown in FIG. 13B. After the dry etching described above, the resist R3 is removed (stripped).

After the process PR7, a process for forming the display element DE1 is performed (the process PR8 in FIG. 11). In the formation of the display element DE1, the stacked film FL1 and the sealing layer SE11 are formed first as shown in FIG. 12G. As shown in FIG. 3, the stacked film FL1 includes the organic layer OR1 contacting the lower electrode LE1 through the pixel aperture AP1, the upper electrode UE1 covering the organic layer OR1, and the cap layer CP1 covering the upper electrode UE1. For example, the organic layer OR1, the upper electrode UE1, and the cap layer CP1 may be formed by vapor deposition. The sealing layer SE11 may be formed by, for example, CVD.

The stacked film FL1 and the sealing layer SE11 are formed in the entire mother substrate MB including the surrounding area SA and the margin area BA as well as the display area DA of each panel portion PP. The stacked film FL1 is divided into a plurality of portions by the partition 6 having an overhang shape. The sealing layer SE11 continuously covers these portions, into which the stacked film FL1 has been divided, and the partition 6.

Subsequently, the stacked film FL1 and the sealing layer SE11 are patterned. In this patterning, a resist R4 is provided on the sealing layer SE11 as shown in FIG. 12G. The resist R4 covers the subpixel SP1 and a portion of the partition 6 around the subpixel SP1.

Thereafter, the etching process using the resist R4 as a mask is performed. This process removes the portions exposed from the resist R4 of the stacked film FL1 and the sealing layer SE11 as shown in FIG. 12H. In other words, the portions that overlap the lower electrode LE1 of the stacked film FL1 and the sealing layer SE11 remain, and the other portions are removed. This forms the display element DE1 in the subpixel SP1. For example, this etching process removes the stacked film FL1 and the sealing layer SE11 in the surrounding area SA and the margin area BA. This etching process may include wet etching and dry etching performed in order for the sealing layer SE11, the cap layer CP1, the upper electrode UE1, and the organic layer OR1. After these etching processes, the resist R4 is removed (stripped).

The stacked film FL1 located under the sealing layer SE11 on the partition 6 is also removed in wet etching for the stacked film FL1. This forms a gap between the sealing layer SE11 located above the partition 6 and the partition 6. The stacked film FL1 constituting the display element DE1 is completely surrounded by the sealing layer SE11 and the partition 6. Thus, this stacked film FL1 is not corroded by the wet etching.

After the process PR8, a process for forming the display element DE2 is performed (the process PR9 in FIG. 11). The display element DE2 can be formed by the same procedure as that of the display element DE1. That is, in the formation of the display element DE2, the stacked film FL2 and the sealing layer SE12 are formed in the entire mother substrate MB. The stacked film FL2 includes the organic layer OR2 contacting the lower electrode LE2 through the pixel aperture AP2, the upper electrode UE2 covering the organic layer OR2, and the cap layer CP2 covering the upper electrode UE2 as shown in FIG. 3.

The organic layer OR2, the upper electrode UE2, and the cap layer CP2 may be formed by, for example, vapor deposition. The sealing layer SE12 may be formed by, for example, CVD. The stacked film FL2 is divided into a plurality of portions by the partition 6 having an overhang shape. The sealing layer SE12 continuously covers these portions, into which the stacked film FL2 has been divided, and the partition 6. Patterning these stacked film FL2 and sealing layer SE2 forms the display element DE2 in the subpixel SP2 as shown in FIG. 121. For example, the etching in this patterning removes the stacked film FL2 and the sealing layer SE12 in the surrounding area SA and the margin area BA.

After the process PR9, a process for forming the display element DE3 is performed (the process PR10 in FIG. 11). The display element DE3 can be formed by the same procedures as those of the display elements DE1 and DE2. That is, in the formation of the display element DE3, the stacked film FL3 and the sealing layer SE13 are formed in the entire mother substrate MB. The stacked film FL3 includes the organic layer OR3 contacting the lower electrode LE3 through the pixel aperture AP3, the upper electrode UE3 covering the organic layer OR3, and the cap layer CP3 covering the upper electrode UE3 as shown in FIG. 3.

The organic layer OR3, the upper electrode UE3, and the cap layer CP3 may be formed by, for example, vapor deposition. The sealing layer SE13 may be formed by, for example, CVD. The stacked film FL3 is divided into a plurality of portions by the partition 6 having an overhang shape. The sealing layer SE13 continuously covers these portions, into which the stacked film FL3 has been divided, and the partition 6. Patterning these stacked film FL3 and sealing layer SE13 forms the display element DE3 in the subpixel SP3 as shown in FIG. 12J. For example, the etching in this patterning removes the stacked film FL3 and the sealing layer SE13 in the surrounding area SA and the margin area BA.

Here, the above description assumes that the display elements DE1, DE2, and DE3 are formed in this order. However, the display elements DE1, DE2, and DE3 may be formed in another order.

After the formation of the display elements DE1, DE2, and DE3, the resin layer RS1, the sealing layer SE2, and the resin layer RS2 shown in FIG. 3 are formed in order (the process PR11 in FIG. 11). Further, each panel portion PP is cut out from the mother substrate MB along the cut line CL1 (the process PR12 in FIG. 11).

Subsequently, an inspection is implemented for each panel portion PP (the process PR13 in FIG. 11). For example, the inspection includes the lighting inspection of each of the display elements DE1, DE2, and DE3 using the inspection pad provided in the inspection area TA. After the inspection, the inspection area TA is cut along the cut line CL2 (the process PR14 in FIG. 11). This completes the display panel PNL.

In the same manner as the partition 6, the partition 7 is formed in the surrounding area SA and the margin area BA in the processes PR4 and PR5. That is, in the processes PR4 and PR5, the bottom layer 73 is formed on the rib layer 5, the stem layer 74 is formed on the bottom layer 73, the first thin film 75 is formed on the stem layer 74, and the second thin film 76 is formed on the first thin film 75. However, immediately after the process PR5, the trench portion 79 is not formed in the upper portion 72 of the partition 7. For example, the third layer L3 (the first thin film 65) has a thickness of 100 nm or less in the first embodiment.

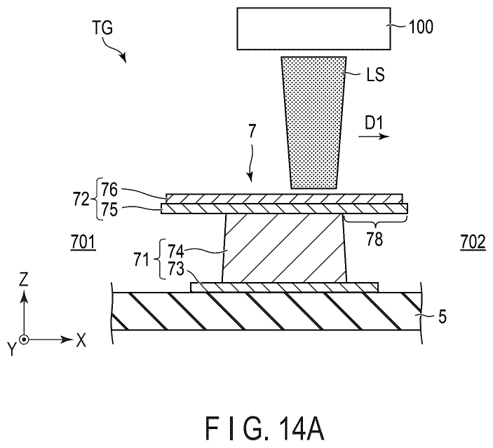

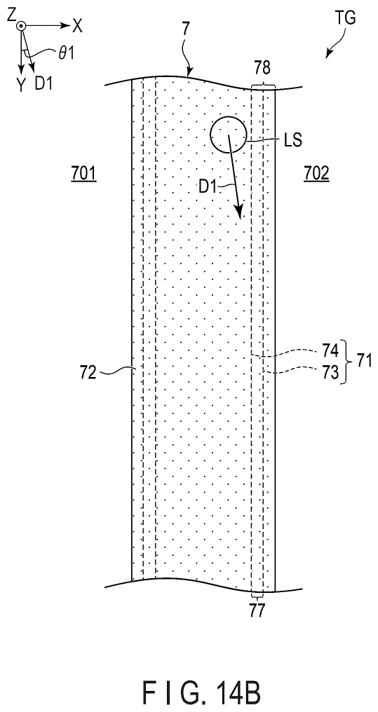

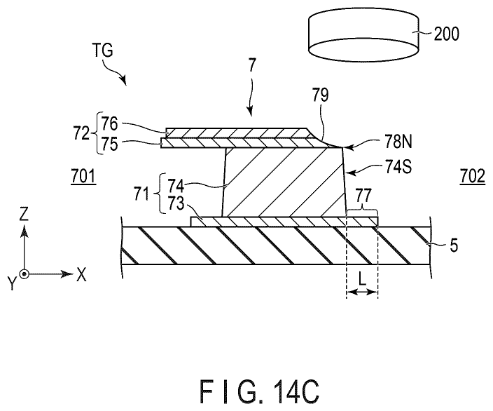

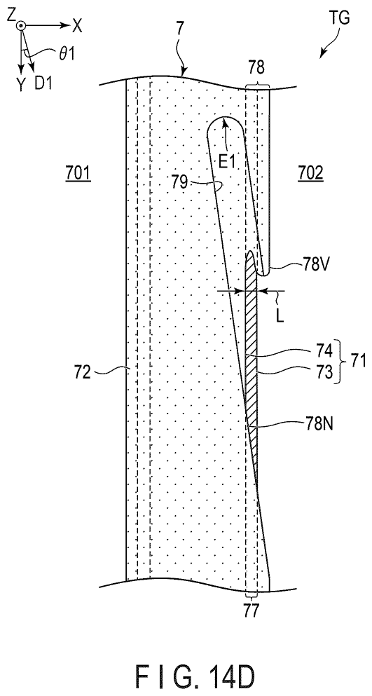

FIG. 14A to FIG. 14D are views showing an example of the processes of removing a portion of the upper portion 72. FIG. 14A and FIG. 14C are schematic cross-sectional views of the processes. FIG. 14B and FIG. 14D are schematic plan views of the processes. FIG. 14B is a cross-sectional view showing a state at the same time as in FIG. 14A. FIG. 14D is a cross-sectional view showing a state at the same time as in FIG. 14C. FIG. 14A and FIG. 14C omit the illustration of the components below the rib layer 5.

The upper portion 72 is irradiated with laser light LS using a laser device 100 as shown in FIG. 14A. At this time, the starting point of processing by the laser light LS overlaps the stem layer 74 as shown in FIG. 14B. Thereafter, the laser light LS scans in the direction D1. That is, the laser light LS scans from the position overlapping the stem layer 74 toward the overhang portion 78 on the partition aperture 702 side. For example, the laser device 100 is configured to emit the laser light LS that is in an infrared wavelength.

The trench portion 79 is formed in the upper portion 72 by the laser light LS scanning as shown in FIG. 14C and FIG. 14D. Further, the portion of the overhang portion 78 is removed by the laser light LS, and the notch 78N and the convex portion 78V are formed on the overhang portion 78. This makes the bottom layer 73 and the protrusion portion 77 visible in plan view. Then, the length L of the protrusion portion 77 is measured using a measurement device 200. The length L can be measured, for example, by analyzing an image in which the protrusion portion 77 is captured in a planar manner.

For example, the processes shown in FIG. 14A to FIG. 14D could be performed after the process PR7 of forming the terminal aperture APt in the rib layer 5. The configuration is not limited to this example. The processes shown in FIG. 14A to FIG. 14D may be performed, for example, after the process PR6 for providing the pixel apertures AP1, AP2, and AP3 in the rib layer 5.

The measurement process may be performed for each of the test patterns TG dispersed in the mother substrate MB as shown in FIG. 4. This case suppresses variations in measurement depending on positions of the mother substrate MB. In another example, the measurement process may be performed for some of the plurality of test patterns TG.

In this manner, the measurement process of the length L of the protrusion portion 77 is performed after removing the part of the overhang portion 78 by the laser light LS in the present embodiment. If the overhang portion 78 is not removed, the length L needs to be measured through a destructive inspection for observing the section of the partition 7. The destructive inspection is difficult to perform in the middle of the manufacturing process of the display device DSP and further requires time and effort.

In contrast, providing the test patterns TG in which the portion of the overhang portion 78 is removed by the laser light LS as in the present embodiment enables the measurement of the length L of the protrusion portion 77 by an observation from the upper side of the mother substrate MB without the destructive inspection. This measurement can be easily performed in the middle of the manufacturing process of the display device DSP. When a failure is confirmed in an inspection using the measurement results, the manufacturing can be suspended without performing the subsequent processes.

In the present embodiment, the portion of the overhang portion 78 is removed by the laser light LS scanning in the direction DI inclined at the angle θ1 with respect to the extending direction (the Y-direction) of the partition 7. If the laser light LS scans in a direction parallel to the extending direction of the partition 7, it is difficult to apply the laser light LS at the root of the overhang portion 78 (the boundary between the upper portion 72 and the stem layer 74) due to the influence of the processing accuracy and the positioning accuracy of the laser device 100.

In contrast, in the present embodiment, the laser light LS surely traverses the root of the overhang portion 78. This eliminates the need of processing and positioning with high accuracy, achieving cost cut and higher yield.

Further, the laser light LS scans from the position overlapping the stem layer 74 toward the overhang portion 78 in the direction D1 in the present embodiment. If the laser light LS scans from the overhang portion 78 side toward the stem layer 74 in the direction opposite to the direction D1, the laser light LS reaches first the end portion of the overhang portion 78 of the partition 7. Thus, the energy of the laser light LS may be concentrated on the end portion of the overhang portion 78. This may cause the laser light LS to penetrate the overhang portion 78 and process the bottom layer 73.

In contrast, in the present embodiment, the laser light LS scans from the position overlapping the stem layer 74 toward the partition aperture 702. Thus, the energy of the laser light LS is scattered on the upper portion 72 and thus is not concentrated on the overhang portion 78. This prevents the laser light LS from processing the bottom layer 73 and achieves the accurate measurement of the protrusion portion 77.

In this manner, the present embodiment can efficiently perform the inspection in the manufacturing of the display device DSP. Various desirable effects can be obtained from the embodiment in addition to the effects explained here.

### Second Embodiment

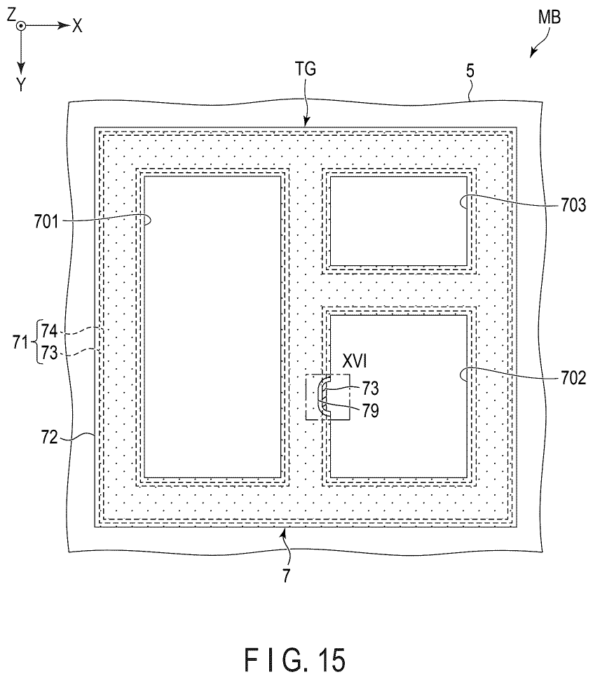

Next, the second embodiment will be described. FIG. 15 is a schematic plan view showing an example of the configuration applicable to the test pattern TG of the mother substrate MB according to the second embodiment. The same elements as those of the first embodiment are denoted by the same reference numbers. Overlapping descriptions of these elements are omitted.

The upper portion 72 has a trench portion 79 located on the partition aperture 702 side as shown in FIG. 15. In the example of FIG. 15, the trench portion 79 is provided between the partition apertures 701 and 702. A portion of the upper portion 72 is lost and a portion of the bottom layer 73 (the portion indicated by hatch lines) is exposed between the trench portion 79 and the partition aperture 702. The position of the trench portion 79 is not limited to the illustrated example. Some exposed portions of the trench portion 79 and the bottom layer 73 may be provided between the partition apertures 701 and 702.

The trench portion 79 is formed by irradiating the upper portion 72 with laser light. This point is to be described later in detail. Irradiating the overhang portion 78 with this laser light removes the portion of the overhang portion 78 and makes a portion of the bottom layer 73 exposed.

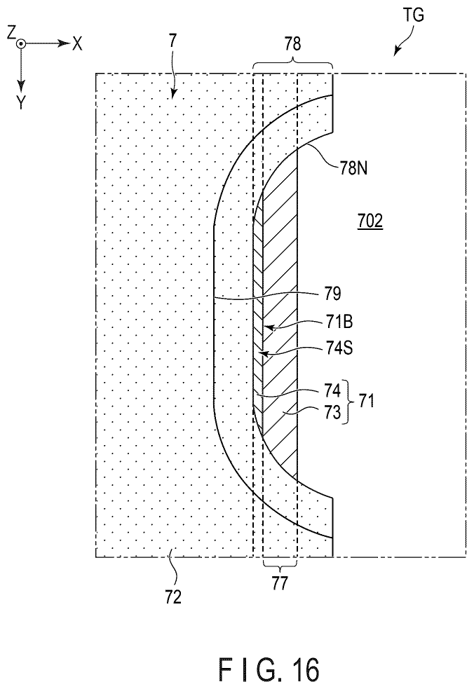

FIG. 16 is an enlarged view of the area surrounded by the chained frame XVI in FIG. 15. FIG. 16 shows the portions that do not overlap the upper portion 72 of the bottom layer 73 and the stem layer 74 by hatch lines.

The overhang portion 78 has the notch 78N. The notch 78N corresponds to the portion removed from the overhang portion 78 by the laser light for forming the trench portion 79. The boundary between the overhang portion 78 and the notch 78N is formed in a round shape. The notch 78N overlaps the boundary 71B between the bottom layer 73 and the stem layer 74 in plan view. The trench portion 79 is formed along the notch 78N.

The cross-sectional configuration of the partition 7 including the notch 78N and the trench portion 79 has the same configuration as the cross section shown in FIG. 10. Further, in an example, the thickness T of the first thin film 75 in the present embodiment is greater than 100 nm.

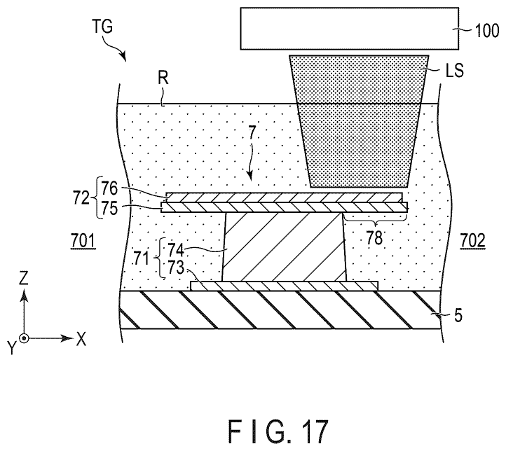

FIG. 17 is a schematic cross-sectional view showing an example of the process of removing a portion of the upper portion 72. FIG. 17 emits the illustration of the components below the rib layer 5.

A resist R covering the partition 7 is formed as shown in FIG. 17. Subsequently, dry etching using the resist R as a mask is performed. After the dry etching, the laser light LS is applied in a part of the overhang portion 78 using the laser device 100. This removes the portions irradiated with the laser light LS of the overhang portion 78 and the resist R and thus forms the notch 78N in the overhang portion 78. Subsequently, the resist R is removed (stripped). After removing the resist R, the length L of the protrusion portion 77 is measured using the measurement device 200 in the same manner as the process shown in FIG. 14C.

As the process shown in FIG. 17, the process PR7 of forming the terminal aperture APt in the rib layer 5 can be used. In this case, the resist R corresponds to the resist R3 shown in FIG. 13A and FIG. 13B. Further, the dry etching performed prior to irradiation of the laser light LS corresponds to the dry etching for forming the terminal aperture APt in the rib layer 5.

As the process shown in FIG. 17, processes other than the process PR7 may be used. For example, as the process shown in FIG. 17, the process PR6 for providing the pixel apertures AP1, AP2, and AP3 in the rib layer 5 can be used. In this case, the resist R corresponds to the resist R2 shown in FIG. 12E and FIG. 12F. Further, the dry etching performed prior to the irradiation of the laser light LS corresponds to the dry etching for forming the pixel apertures AP1, AP2, and AP3 in the rib layer 5.

In the present embodiment, the process of removing the overhang portion 78 by the laser light LS is performed with the partition 7 being covered with the resist R. Thus, a portion of the energy of the laser light LS is used for processing the resist R. In this case, compared to cases where no resist R is provided, the overhang portion 78 can be performed substantially without damaging the bottom layer 73.

Furthermore, in the present embodiment, the process of removing the overhang portion 78 by the laser light LS is performed after the dry etching. This dry etching changes the properties of the resist R. Thus, more of the energy of the laser light LS is used for processing the resist R compared to the cases where the irradiation of the laser light LS is performed before the dry etching. This further decreases the damage to the bottom layer 73.

In the first embodiment, the laser light LS scans in one direction. In contrast, in the present embodiment, the laser light LS is applied over a certain area. Thus, in the present embodiment, the overhang portion 78 can be removed even if the thickness T of the first thin film 75 is thicker than that in the first embodiment. For example, in the present embodiment, the overhang portion 78 can be removed even if the thickness T of the first thin film 75 is greater than 100 nm.

Furthermore, the mother substrate MB and the manufacturing method of the mother substrate according to the second embodiment exhibit the same effects as those of the mother substrate MB and the manufacturing method of the mother substrate according to the first embodiment.

### Third Embodiment

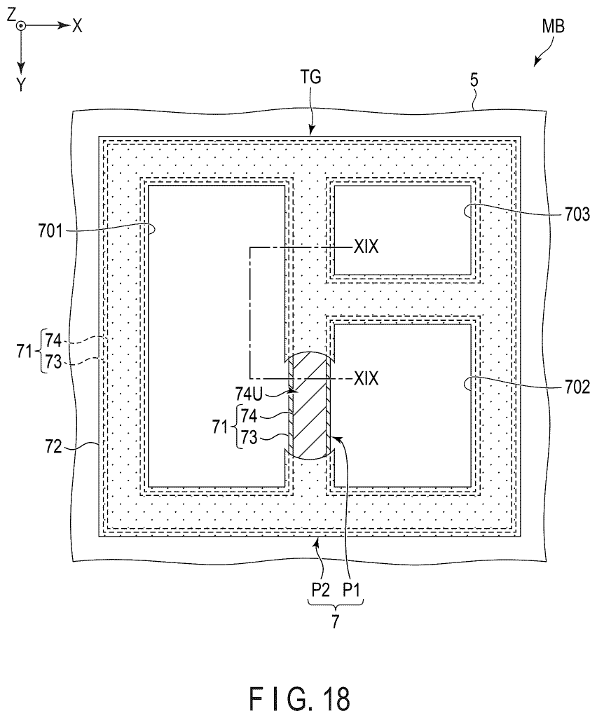

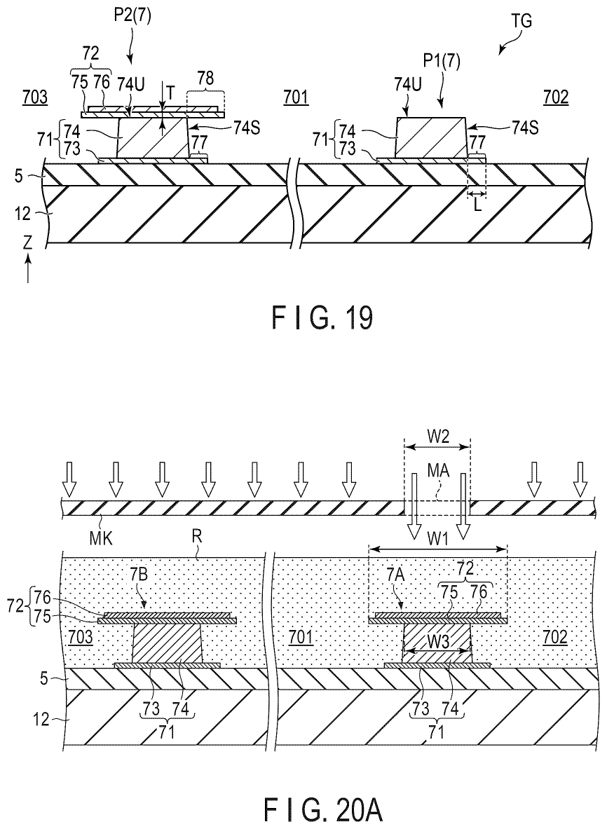

Next, the third embodiment will be described. FIG. 18 is a schematic plan view showing an example of the configuration applicable to the test pattern TG of the mother substrate MB according to the third embodiment. FIG. 19 is a schematic cross-sectional view of the mother substrate MB along the XIX-XIX line of FIG. 18. FIG. 19 omits the illustration of the components below the organic insulating layer 12.

The partition 7 comprises a first portion P1 (the portion shown by the hatch lines) and a second portion P2 (the portion shown by the dotted pattern). In the example of FIG. 18, the first portion P1 is located between the partition apertures 701 and 702. In the partition 7, the portion excluding the first portion P1 corresponds to the second portion P2. The position at which the first portion P1 is provided is not limited to this example.

As shown in FIG. 18 and FIG. 19, the first portion P1 includes the lower portion 71 (the bottom layer 73 and the stem layer 74) in the same manner as the partition 6. The first portion P1 does not include the upper portion 72 (the first thin film 75 and the second thin film 76). Thus, an upper surface 74U of the stem layer 74 is exposed in the first portion P1.

In contrast, the second portion P2 includes the lower portion 71 (the bottom layer 73 and the stem layer 74) and the upper portion 72 (the first thin film 75 and the second thin film 76) as shown in. FIG. 19. Thus, the upper surface 74U of the stem layer 74 is covered with the upper portion 72 in the second portion P2. In an example, the thickness T of the first thin film 75 in the second portion P2 is greater than 100 nm.

FIG. 18 shows the outer shapes of the bottom layer 73 and the stem layer 74 of the second portion P2 by broken lines. For example, the bottom layer 73 of the second portion P2 is connected to the bottom layer 73 of the first portion P1. Similarly, the stem layer 74 of the second portion P2 is connected to the stem layer 74 of the first portion P1.

The lower portions 71 of the first portion P1 and the second portion P2 are provided on the rib layers 5 as shown in FIG. 19. In the examples of FIG. 18 and FIG. 19, the rib layer 5 is flat between the partition aperture 701 and the first portion Pl and between the partition aperture 702 and the first portion P1. However, the rib layer 5 may have an aperture located around the first portion P1.

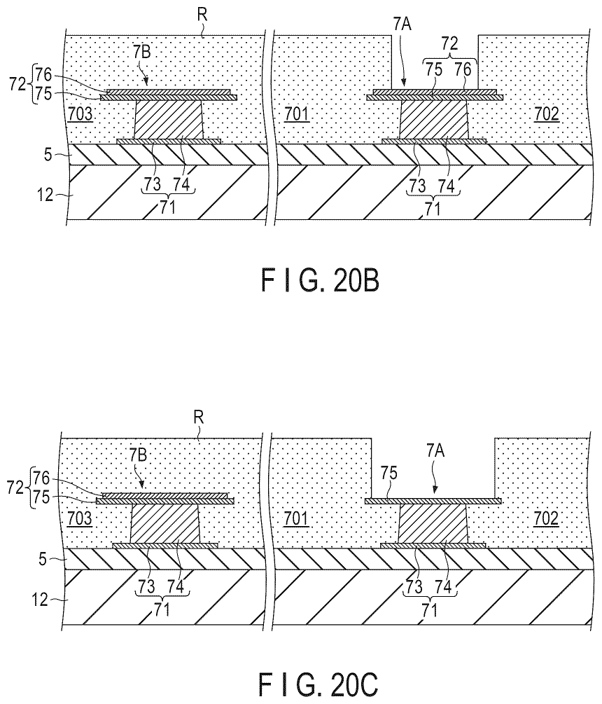

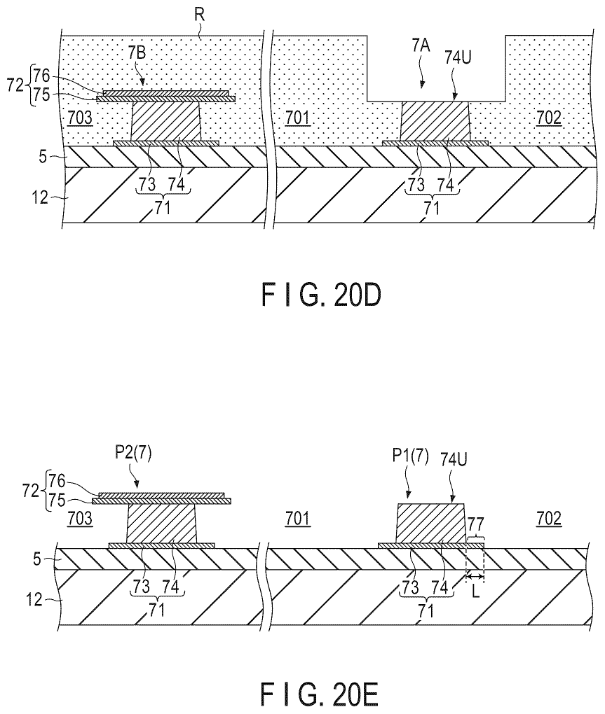

FIG. 20A to FIG. 20E are schematic cross-sectional views showing an example of the process for forming the first portion Pl. These cross-sectional views show the same portion as the one shown in FIG. 19 and omit the illustration of the components below the organic insulating layer 12. In the following description, the portion in which the first portion P1 is formed of the partition 7 is referred to as a partition 7A, and the portion in which the second portion P2 is formed of the partition 7 is referred to as a partition 7B.

In the formation of the first portion P1, the resist R covering the partitions 7A and 7B are formed as shown in FIG. 20A. Further, the resist R is exposed to light using a mask MK as shown by several arrows. The mask MK has an aperture MA above the partition 7A. A width W2 of the aperture MA is smaller than a width W1 of the upper portion 72 (the width of the first thin film 75 in FIG. 20A). In an example, the width W2 is about 2 μm smaller than the width W1. In another example, the width W2 is almost equivalent to a width W3 of the stem layer 74.

The resist R is, for example, a positive resist. Thus, the portion exposed to light of the resist R is removed by a development process as shown in FIG. 20B. Thus, a portion of the upper portion 72 of the partition 7A is exposed from the resist R between the partition apertures 701 and 702. The width of the portion removed in the developing process is almost equivalent to the width W2 of the aperture MA of the mask MK.

In FIG. 20B, the partition 7B is entirely covered with the resist R. Further, a part of the second thin film 76 of the partition 7A is exposed from the resist R. Furthermore, both end portions of the upper portion 72 of the partition 7A are covered with the resist R. In FIG. 20B, both end portions of the first thin film 75 and the second thin film 76 of the partition 7A are covered with the resist R. The rib layer 5 around the partition 7A is not exposed from the resist R.

Next, an etching process is performed with the resist R provided. The etching process includes wet etching (the first etching) shown in FIG. 20C and dry etching (the second etching) shown in FIG. 20D.

As shown in FIG. 20C, the second thin film 76 of the partition 7A is removed by wet etching. This exposes the upper surface of the first thin film 75 of the partition 7A. The upper portion 72 of the partition 7B is covered with the resist R and thus is not removed by the wet etching.

After the wet etching, both ends of the first thin film 75 of the partition 7A may be covered with the resist R or may be exposed from the resist R as shown in FIG. 20C.

After this wet etching, the first thin film 75 of the partition 7A is removed by dry etching as shown in FIG. 20D. This removes the upper portion 72 of the partition 7A and makes the upper surface of the stem layer 74 of the partition 7A exposed. The upper portion 72 of the partition 7B is covered with the resist R and thus is not removed by the dry etching.

After the etching process, the resist R is removed (stripped) as shown in FIG. 20E. These processes complete the formation of the first portion Pl and the second portion P2. The portion located around the first portion P1 of the rib layer 5 is covered with the resist R and thus is flat. Specifically, the rib layer 5 is flat between the partition aperture 701 and the first portion Pl and between the partition aperture 702 and the first portion P1.

In the same manner as in the first and second embodiments, the length L of the protrusion portion 77 is measured using the first portion P1 formed in this manner.

As the processes shown in FIG. 20A to FIG. 20E, the process PR7 of forming the terminal aperture APt in the rib layer 5 can be used. In this case, the resist R corresponds to the resist R3 shown in FIG. 13A and FIG. 13B. Further, the dry etching for removing the first thin film 75 of the partition 7A corresponds to the dry etching for forming the terminal aperture APt in the rib layer 5. The dry etching for removing the first thin film 75 of the partition 7A and the dry etching for forming the terminal aperture APt in the rib layer 5 may be performed simultaneously or separately. That is, the dry etching for forming the terminal aperture APt in the rib layer 5 (the third etching) may be performed after the dry etching for removing the first thin film 75 of the partition 7A. The removal of the first thin film 75 and the formation of the terminal aperture APt can be performed more accurately and precisely when the dry etching is performed separately than when the dry etching is performed simultaneously. On the other hand, performing the dry etching simultaneously can suppress the increase in the number of processes.

In the present embodiment, performing the dry etching removes the upper portion 72 of the first portion P1. Thus, the upper portion 72 (the overhang portion 78) can be removed even when the thickness T of the first thin film 75 is large. For example, in the present embodiment, the upper portion 72 can be removed even if the thickness T of the first thin film 75 is greater than 100 nm.

In the present embodiment, the width W2 of the aperture MA of the mask MK is smaller than the width W1 of the upper portion 72. If the width W2 is greater than the width W1, the protrusion portion 77 has the risk of being corroded by etching. Thus, making the width W2 smaller than the width W1 can suppress the corrosion of the protrusion portion 77.

Furthermore, if the width W2 is too small compared to the width W1, the overhang portion 78 may not be completely removed and may remain. If the remaining overhang portion 78 is detached from the mother substrate MB in the manufacturing process, it may adversely affect other products and equipment and deteriorate the yield. In the present embodiment, the width W2 is approximately 2 μm smaller than the width W1. In another example, the width W2 is almost equivalent to the width W3 of the stem layer 74. These conditions enable the overhang portion 78 to be completely removed by etching, thereby suppressing a decrease in the yield.

Furthermore, the mother substrate MB and the manufacturing method of the mother substrate according to the third embodiment exhibit the same effects as those of the mother substrate MB and the manufacturing method of the mother substrate according to the first and second embodiments.

All of the mother substrates and the manufacturing methods of the same that can be implemented by a person of ordinary skill in the art through arbitrary design changes to the mother substrates and the manufacturing methods of the same described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A mother substrate, comprising:
a plurality of panel portions each including a display area and a surrounding area around the display area;
a margin area around the plurality of panel portions;
a lower electrode provided in the display area;
a rib layer provided in the panel portion and the margin area and having a pixel aperture overlapping the lower electrode; and
a first partition provided in the margin area, wherein
the first partition includes:
a first bottom layer provided on the rib layer;
a first stem layer provided on the first bottom layer and having conductivity; and
a first upper portion provided on the first stem layer,
the first bottom layer has a protrusion portion protruding relative to a side surface of the first stem layer,
the first upper portion has an overhang portion protruding relative to the side surface of the first stem layer,
the overhang portion has a notch overlapping the protrusion portion in plan view, and
the notch overlaps a boundary between the first bottom layer and the first stem layer in plan view.

2. The mother substrate of claim 1, wherein
the first upper portion further has a trench portion extending in a second direction inclined with respect to a first direction in which the first partition extends, and
the notch is adjacent to the trench portion.

3. The mother substrate of claim 2, wherein
the overhang portion further has a convex portion protruding in the first direction, and
the convex portion is adjacent to the notch.

4. The mother substrate of claim 2, wherein
an end portion of the trench portion overlaps the first stem layer in plan view.

5. The mother substrate of claim 2, wherein
the second direction is inclined at an acute angle with respect to the first direction.

6. The mother substrate of claim 2, wherein
the first upper portion has:
a first thin film provided on the first stem layer and formed of a material including titanium; and
a second thin film provided on the first thin film and formed of an ITO, and
a thickness of the first thin film is 100 nm or less.

7. The mother substrate of claim 1, wherein
the first upper portion further has a trench portion along the notch.

8. The mother substrate of claim 7, wherein
a boundary between the overhang portion and the notch is formed in a round shape.

9. The mother substrate of claim 2, wherein
the first partition further includes a first partition aperture and a second partition aperture adjacent to the first partition aperture, and
the trench portion is provided between the first partition aperture and the second partition aperture.

10. A mother substrate, comprising:
a plurality of panel portions each including a display area and a surrounding area around the display area;
a margin area around the plurality of panel portions;
a lower electrode provided in the display area;
a rib layer provided in the panel portion and the margin area and having a pixel aperture overlapping the lower electrode; and
a first partition provided in the margin area, wherein
the first partition includes:
a first bottom layer provided on the rib layer;
a first stem layer provided on the first bottom layer and having conductivity;
a first upper portion provided on the first stem layer;
a first partition aperture;
a second partition aperture adjacent to the first partition aperture; and
a first portion located between the first partition aperture and the second partition aperture,
the first bottom layer has a protrusion portion protruding from a side surface of the first stem layer, and
an upper surface of the first stem layer is exposed in the first portion.

11. The mother substrate of claim 10, wherein
the rib layer is flat between the first partition aperture and the first portion and between the second partition aperture and the first portion.

12. The mother substrate of claim 7, wherein
the first upper portion includes:
a first thin film provided on the first stem layer and formed of a material including titanium; and
a second thin film provided on the first thin film and formed of an ITO, and
a thickness of the first thin film is greater than 100 nm.

13. The mother substrate of claim 1, further comprising:
a second partition provided in the display area and surrounding the pixel aperture, wherein
the second partition includes:
a second bottom layer provided on the rib layer;
a second stem layer provided on the second bottom layer; and
a second upper portion provided on the second stem layer.

14. The mother substrate of claim 13, further comprising:
an organic layer contacting the lower electrode through the pixel aperture;
an upper electrode provided on the organic layer and contacting the second stem layer;
a cap layer provided on the upper electrode; and
a sealing layer provided on the cap layer, wherein
the second partition surrounds the lower electrode, the organic layer, the upper electrode, and the cap layer.

15. A manufacturing method of a mother substrate, comprising steps of:
preparing a substrate including a plurality of panel portions each including a display area and a surrounding area around the display area and a margin area around the plurality of panel portions;
forming a lower electrode in the display area;
forming a rib layer covering the plurality of panel portions and the margin area;
forming a first partition in the margin area, the first partition including a first bottom layer formed on the rib layer, a first stem layer formed on the first bottom layer and having conductivity, and a first upper portion formed on the first stem layer;
making a laser to scan in a second direction inclined with respect to a first direction in which the first partition extends to remove a portion of an overhang portion protruding relative to a side surface of the first stem layer of the upper portion; and
measuring a length of a protrusion portion of the first bottom layer, the protrusion portion protruding relative to the side surface of the first stem layer.

16. The manufacturing method of claim 15, further comprising:
making the laser to scan a portion overlapping the first stem layer of the first upper portion toward the overhang portion, in the step of removing the portion of the overhang portion.

17. The manufacturing method of claim 15, further comprising:
forming a conductive layer in the surrounding area prior to the step of forming the rib layer;
forming the rib layer covering the conductive layer in the step of forming the rib layer; and
forming a terminal aperture overlapping the conductive layer in the rib layer between the step of forming the first partition and the step of removing the portion of the overhang portion.

18. The manufacturing method of claim 15, wherein
the step of forming the first upper portion includes a step of forming a first thin film of a material including titanium on the first stem layer and a step of forming a second thin film of an ITO on the first thin film, and
the first thin film is formed to have a thickness of 100 nm or less.

19. A manufacturing method of a mother substrate, comprising steps of:
preparing a substrate including a plurality of panel portions each including a display area and a surrounding area around the display area and a margin area around the plurality of panel portions;
forming a lower electrode in the display area;
forming a rib layer covering the plurality of panel portions and the margin area;
forming a first partition in the margin area, the first partition including a first bottom layer formed on the rib layer, a first stem layer formed on the first bottom layer and having conductivity, and a first upper portion formed on the first stem layer;
forming a resist covering the first partition;
simultaneously removing with a laser a portion of an overhang portion protruding relative to a side surface of the first stem layer of the first upper portion and a portion overlapping the overhang portion of the resist; and
measuring a length of a protrusion portion of the first bottom layer, the protrusion portion protruding relative to the side surface of the first stem layer.

20. The manufacturing method of claim 19, further comprising:
forming a conductive layer in the surrounding area prior to the step of forming the rib layer;
forming the rib layer covering the conductive layer in the step of forming the rib layer; and
performing dry etching between the step of forming the resist and the step of removing the portion of the overhang portion to form a terminal aperture overlapping the conductive layer in the rib layer.

21. The manufacturing method of claim 19, wherein
the step of forming the first upper portion includes a step of forming a first thin film of a material including titanium on the first stem layer and a step of forming a second thin film of an ITO on the first thin film, and
the first thin film is formed to have a thickness greater than 100 nm.

22. A manufacturing method of a mother substrate, comprising steps of:
preparing a substrate including a plurality of panel portions each including a display area and a surrounding area around the display area and a margin area around the plurality of panel portions;
forming a lower electrode in the display area;
forming a rib layer covering the plurality of panel portions and the margin area;
forming a first partition in the margin area, the first partition including a first bottom layer formed on the rib layer, a first stem layer formed on the first bottom layer and having conductivity, a first upper portion formed on the first stem layer, a first partition aperture, and a second partition aperture adjacent to the first partition aperture;
forming a resist from which at least a portion of the first upper portion is exposed between the first partition aperture and the second partition aperture;
performing etching to remove the portion exposed from the resist of the first upper portion; and
measuring a length of a protrusion portion of the first bottom layer, the protrusion portion protruding relative to the side surface of the first stem layer.

23. The manufacturing method of claim 22, wherein
the step of forming the first upper portion includes a step of forming a first thin film of a material including titanium on the first stem layer and a step of forming a second thin film of an ITO on the first thin film, and
the first thin film is formed to have a thickness greater than 100 nm.

24. The manufacturing method of claim 23, wherein
the step of removing the first upper portion includes:
performing a first etching to remove a portion exposed from the resist of the second thin film; and
performing a second etching to remove a portion exposed from the resist of the first thin film.

25. The manufacturing method of claim 24, wherein
forming a conductive layer in the surrounding area prior to the step of forming the rib layer;
forming the rib layer covering the conductive layer in the step of forming the rib layer; and
performing the second etching to form a terminal aperture overlapping the conductive layer in the rib layer.

26. The manufacturing method of claim 24, wherein
the first etching is wet etching, and
the second etching is dry etching.

27. The manufacturing method of claim 24, further comprising:
forming a conductive layer in the surrounding area prior to the step of forming the rib layer;
forming the rib layer covering the conductive layer in the step of forming the rib layer; and
performing a third etching, after the second etching, to form a terminal aperture overlapping the conductive layer in the rib layer.

28. The manufacturing method of claim 27, wherein
the first etching is wet etching,
the second etching is dry etching, and
the third etching is dry etching.

29. The manufacturing method of claim 22, wherein
in the step of forming the resist, the resist is exposed to light using a mask having an aperture having a width smaller than a width of the first upper portion.

30. The manufacturing method of claim 15, further comprising:
forming a second partition in the display area in the step of forming the first partition, the second partition including a second bottom layer formed on the rib layer, a second stem layer formed on the second bottom layer and having conductivity, and a second upper portion formed on the second stem layer.
